(19) United States
(12) Patent Application Publication
(10) Pub. No.: US 2008/0036094 A1
(43) Pub. Date: Feb. 14, 2008

(54) Functional device-mounted module and a method for mounting functional device-mounted module

(75) Inventor: Yoshihiro Yoneda, Hakusan-shi (JP)

Correspondence Address: OLIFF & BERRIDGE, PLC, P.O. BOX 320850, ALEXANDRIA, VA, 22320-4850, US

(73) Assignee: SONY CHEMICAL & INFORMATION DEVICE CORPORATION, Tokyo (JP)

(21) Appl. No.: 11/896,580

(22) Filed: Sep. 4, 2007

Related U.S. Application Data
(63) Continuation of application No. PCT/JP2006/303718, filed on Feb. 28, 2006.

(30) Foreign Application Priority Data
Mar. 4, 2005 (JP) 2005-060289

(51) Int. Cl. H01L 23/48

(52) U.S. Cl. 257/774

(57) ABSTRACT

This disclosure provides a technique that prevents debonding at an interface between a functional device and a resin on reflow soldering in a functional device-mounted module requiring a hollow structure. Also disclosed is a functional device having a functional portion mounted on a substrate formed with predetermined wiring patterns, wherein the functional portion of the functional device is arranged in a receiving space, and the substrate is provided with a hole which communicates with the receiving space and a solder-introducing portion made of a metallic material compatible with solder. During solder reflowing, the functional device-mounted module is placed on a mounting substrate such that the solder-introducing portion of the functional device-mounted module contacts a solder paste, and solder is melted with heat. Water inside the receiving space is thus discharged, and solder is introduced into the hole due to surface tension, and the interior of the receiving space is sealed.

### CROSS-REFERENCE TO RELATED APPLICATIONS

The present invention is a Continuation of International Application No. PCT/JP2006/303718 filed Feb. 28, 2006, which claims priority to Japan Patent Document No. 2005-060289, filed on Mar. 4, 2005. The entire disclosures of the prior applications are hereby incorporated by reference herein in its entirety.

### BACKGROUND

The present invention relates to a functional device-mounted module requiring a hollow structure, such as parts for MEMS (Micro Electro Mechanical System), SAW (Surface Acoustic Wave) filters, etc.

An exemplary functional device-mounted module requiring such a hollow structure is described in JPA07-143284, and is shown in FIG. 6.

As shown in FIG. 6, in this functional device-mounted module 90, a functional device 92 is arranged in a vessel 91 made of a ceramic material and mounted thereon by die bonding, and a bonding pad 94 and the functional device 92 are electrically connected by bonding wires 93. An opening portion of the vessel 91 is covered with a lid 95 made of a ceramic material or a metal.

Recently, a technique has been proposed, in which a functional device is mounted on a substrate by so-called face-down bonding to form a hollow space between the functional device and the substrate, whereby sealing is performed with a resin.

However, the prior art techniques may have problems in that parts absorb water and the absorbed water is collected inside the hollow space. The evaporation of the water on reflow soldering raises the inner pressure and causes debonding at an interface between the functional device and the resin.

### SUMMARY

This disclosure is directed toward solving the problems of such prior art, and provides a technique which can prevent debonding at an interface between a functional device and a resin on reflow soldering in a functional device-mounted module requiring a hollow structure.

In embodiments, this disclosure is directed toward a functional device-mounted module in which a functional device having a given functional portion is mounted on a substrate formed with predetermined wiring patterns. The functional portion of the functional device is arranged in a predetermined receiving space, and the functional device-mounted module includes a hole that communicates with the receiving space and a solder-introducing portion made of a metallic material that is compatible with solder in order to introduce the solder into the hole.

In embodiments, the solder-introducing portion is formed by applying a coating onto an inner wall of the hole and along a surface-mounting portion from the inner wall of the hole using a metallic material.

In embodiments, the claimed invention may be constructed such that the receiving space is formed between the functional portion of the functional device and the substrate by mounting the functional device on the substrate so as to face the functional portion to the substrate.

In embodiments, the functional device is mounted on the substrate and arranged in the receiving space formed on the substrate having the predetermined wiring patterns by covering the substrate with a lid.

The present disclosure is directed, for example, to a method for mounting, on a mounting substrate, a functional device-mounted module in which a functional device having a given functional portion is mounted on a substrate having predetermined wiring patterns. The functional portion of the functional device is arranged in a predetermined receiving space, a hole is formed on the substrate which communicates with the receiving space and a solder-introducing portion made of a metallic material that is compatible with solder is utilized in order to introduce the solder into the hole. The method may, for example, comprise the steps of: arranging the solder on the mounting substrate at a predetermined position, placing the functional device-mounted module on a mounting substrate in a state that the hole is opposite to the solder, and closing the hole by introducing the solder into the hole by melting the solder with heat.

In embodiments, the step of introducing the solder into the hole may be performed during a step of electrically connecting a connecting terminal of the functional device-mounted module to a connecting terminal of the mounting substrate by reflow soldering.

In embodiments, a functional device-mounted module in which the solder-introducing portion may be formed by applying a coating on an inner wall of the hole and along a surface-mounting portion from the inner wall of the hole using a metallic material.

In embodiments, a functional device-mounted module may have a structure in which the receiving space is formed between the functional portion of the functional device and the substrate by mounting the functional device on the substrate so as to face the functional portion to the substrate.

In embodiments, this disclosure is also directed toward a functional device-mounted module in which the functional device is arranged in the receiving space formed on the substrate having predetermined wiring patterns by covering the substrate with a lid, wherein the functional device is mounted on the substrate.

In embodiments, the substrate may include a hole that communicates with the receiving space, and a solder-introducing portion which is made of a metallic material compatible with solder. The module is placed on the mounting substrate in such a state that the solder-introducing portion faces the solder arranged at a predetermined position on the mounting substrate, and the solder is then melted by applying heat.

During such heating, water inside the receiving space is discharged, and melted solder is introduced into the hole by surface tension so that the interior of the receiving space is sealed with the introduced solder. As a result, debonding of the sealing resin at the interface caused by the evaporation of the water inside the receiving space during solder reflowing can be prevented. Accordingly, when the solder-introducing portion is formed by applying the coating using a predetermined metal material applied to the inner wall of the hole and along the surface-mounting portion of the inner wall of the hole, solder can be more simply and effectively introduced into the hole.

Furthermore, when, for example, the functional device is mounted on the substrate such that the functional portion is arranged opposite to the substrate, and the receiving space is formed between the functional portion of the functional device and the substrate, the resin can be prevented from debonding at the interface due to the evaporation of the water inside the receiving space during the solder reflow. This result may be particularly effective in cases involving an extremely thin functional device-mounted module.

Additionally, if the step of introducing the solder into the hole is performed during the step of electrically connecting the connecting terminal of the functional device-mounted module with the connecting terminal of the mounting substrate by reflow soldering, mounting can be performed without increasing the number of steps.

Furthermore, the present invention can be applied to a functional device-mounted module in which the functional device is arranged and mounted on the substrate in the receiving space, which is formed with the given wiring patterns formed on the substrate, by covering the substrate with a lid.

Accordingly, the resin can be prevented from interface debonding due to the evaporation of the water inside the receiving space during solder reflowing, unlike various conventional types of functional device-mounted modules.

In embodiments, resin can be prevented from interface debonding due to the evaporation of the water inside the receiving space during solder reflowing.

### BRIEF DESCRIPTION OF THE DRAWINGS

FIG. 1 is a sectional view showing the construction of an embodiment of the functional device-mounted module according to the claimed invention.

FIG. 2 is a plan view, on a front face side, showing the construction of the same functional device-mounted module before the device is mounted.

FIG. 3 is a plan view, on a back face side, showing the construction of the same functional device-mounted module.

FIGS. 4(a) to 4(c) are processing diagrams showing an embodiment of a method for mounting a functional device-mounted module according to the present invention.

FIG. 5 is a schematic construction view showing another embodiment of the present invention.

FIG. 6 is a schematic sectional view showing the construction of the conventional functional device-mounted module.

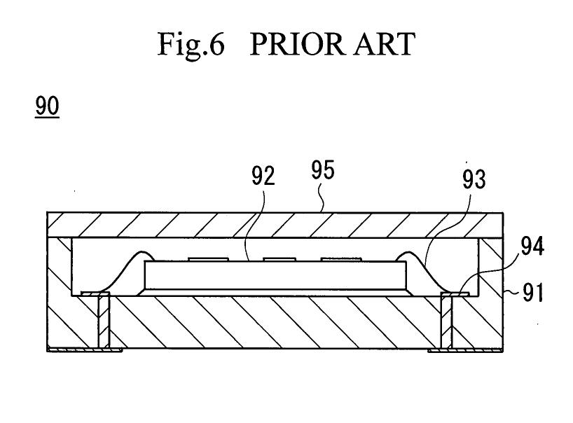

### DETAILED DESCRIPTION OF EMBODIMENTS

In the following, embodiments of the present disclosure will be explained in detail with reference to the drawings.

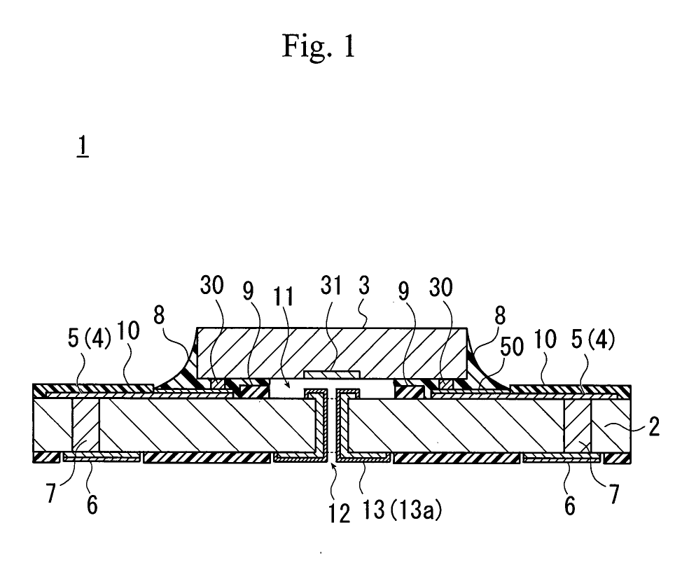

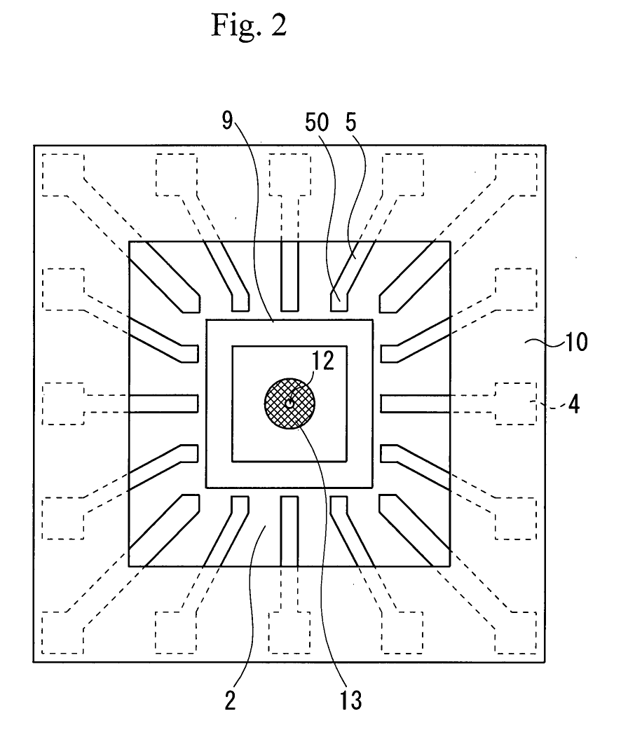

As shown in FIG. 1 to FIG. 3, the functional device-mounted module 1 of the present embodiment is constructed such that a functional device 3 having a given functional portion 31 for an MEMS, is mounted on a given substrate 2, for example.

Predetermined wiring patterns 5 having connecting terminals 4 are formed on the substrate 2, and a connecting portion 50 of each of the wiring patterns 5 is electrically connected to a bump 30 of the functional device 3 by means of an anisotropically electroconductive adhesive or ultrasonic bonding, for example.

Connecting terminals 6 are formed on the back face of the substrate 2, and the connecting terminal 6 is electrically connected to the connecting terminal 4 of the wiring pattern 5 via an electroconductive material 7 inside a through-hole.

In embodiments, the functional portion 31 of the functional device 3 is arranged opposite to the substrate 2, and the functional device 3 is fixedly bonded (sealed) to the substrate 2 with a sealing resin 8 of a thermosetting type, for example.

In this case, for example, an inner damming portion 9 having a rectangular ring-like shape is provided on the substrate 2 immediately under the functional device 3, that is, in an area inside the functional device 3.

This inner damming portion 9 is disposed around the functional portion 31 of the functional device 3 and the sealing resin 8 is dammed by the inner damming portion and the lower face of the functional device 3 so that a receiving space 11 is formed between the functional portion 31 of the functional device 3 and the substrate 2.

Although the size of the receiving space 11 is not particularly limited in the present disclosure, it is the size of the inner damming portion 9 may be formed so as to set the distance between the inner damming portion and the functional device 31 around of the functional device 31 to be 100 to 800 μm, such as 500 to 700 μm in view of preventing flow out of the sealing resin 8 into the receiving space 11.

The ratio in area between the functional portion 31 and the receiving space 11 is set at, for example, 1:1.5 to 1:1000, such as 1:4 to 1:840.

Further, in embodiments, an outer damming portion 10 having a rectangular ring-like shape, for example, is provided on the substrate 2 in an area outside the functional device 3 such that the outer damming portion 10 surrounds the functional device 3.

The outer damming portion 10 dams the sealing resin 8 by a step between the damming portion 10 and the substrate 2, and also protects the wiring patterns 5. The damming portion 10 is provided to cover the outer connecting terminals 4 on the substrate 2.

Although the material for the inner damming portion 9 and the outer damming portion 10 is not particularly limited in the present invention, for example, a solder resist, a resin for silk printing, etc. may be used from the standpoint of cost reduction.

Further, the thickness of the inner damming portion 9 may be set, from the standpoint of assuredly damming the liquid sealing resin 8, such that the distance between the pipe portion 9 and the lower face of the functional device 3 is, for example, around 5 to 50 μm.

On the other hand, the thickness of the outer damming portion 10 may be set at around 30 to 50 μm from the standpoint of assuredly damming the liquid sealing resin 8.

The methods for forming the inner damming portion 9 and the outer damming portion 10 are not limited in the present disclosure, but they may be formed by an electrostatic coating method, for example, so as to improve productivity.

In embodiments, in order to mount the functional device 3 on the substrate 2, the functional device 3 may be arranged such that its functional portion 31 is arranged opposite to the substrate 2, and the connecting portion 50 on each of the wiring patterns 5 of the substrate 2 is electrically connected to the bump 30 of the functional device 3.

Then, the liquid sealing resin 8 of an epoxy type, for example, is dropped in an area between the functional device 3 and the outer damming portion 10 on the substrate 2 by using a nozzle (not shown), for example.

At that time, the dropped sealing resin 8 spreads in an area between the inner damming portion 9 and the outer damming portion 10 on the substrate 2. However, the sealing resin flows 8 along the inner damming portion 9, while the sealing resin 8 is dammed, at a minute gap between the lower face of the functional device 3 and the inner damming portion 9, by the capillary phenomenon and the surface tension. Accordingly, the dropped sealing resin 8 does not enter into the receiving space 11.

Thereafter, the sealing resin 8 is filled on the substrate 2 in the area between the inner damming portion 9 and the outer damming portion 10 by continuously dropping the sealing resin 8. Then, the sealing resin 8 is cured by heating, for example.

In embodiments, for example, a central portion of the substrate 2 may be provided with a hole 12 which communicates with the receiving space 11 and penetrated to the back side of the substrate 2.

A solder-introducing portion 13 is provided on the entire inner wall of the hole 12 and a surface-mounting portion on the back face of the substrate 2 by continuously coating of a given metallic material that is compatible with solder.

In this disclosure, the coating material for the solder-introducing portion 13 is not limited, but gold may used from the standpoint of ensuring compatibility with the solder.

Although the coating method is not particularly limited, coating may be performed by plating, from the standpoint of improving the mass productivity.

Furthermore, it may be beneficial to construct the solder-introducing portion 13 such that the introducing face 13a has a sufficient area around the hole 12 at the surface mounting portion on the back face side of the substrate 2 in order to contact with the below mentioned solder paste 23.

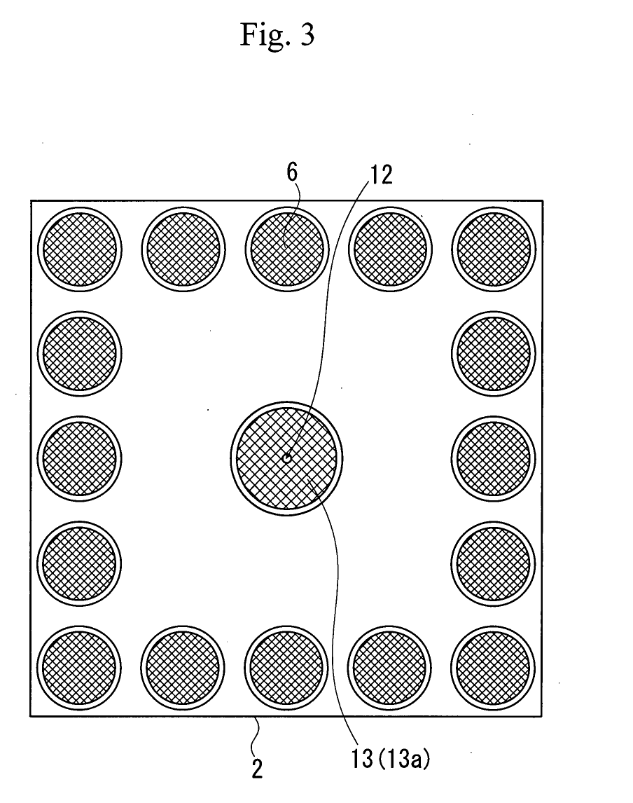

Although the shape of the introducing face 13a of the solder-introducing portion 13 is not limited by this disclosure, the introducing face 13a may be formed in a circular shape as shown in FIG. 3, for example, from the standpoint of the shape stability.

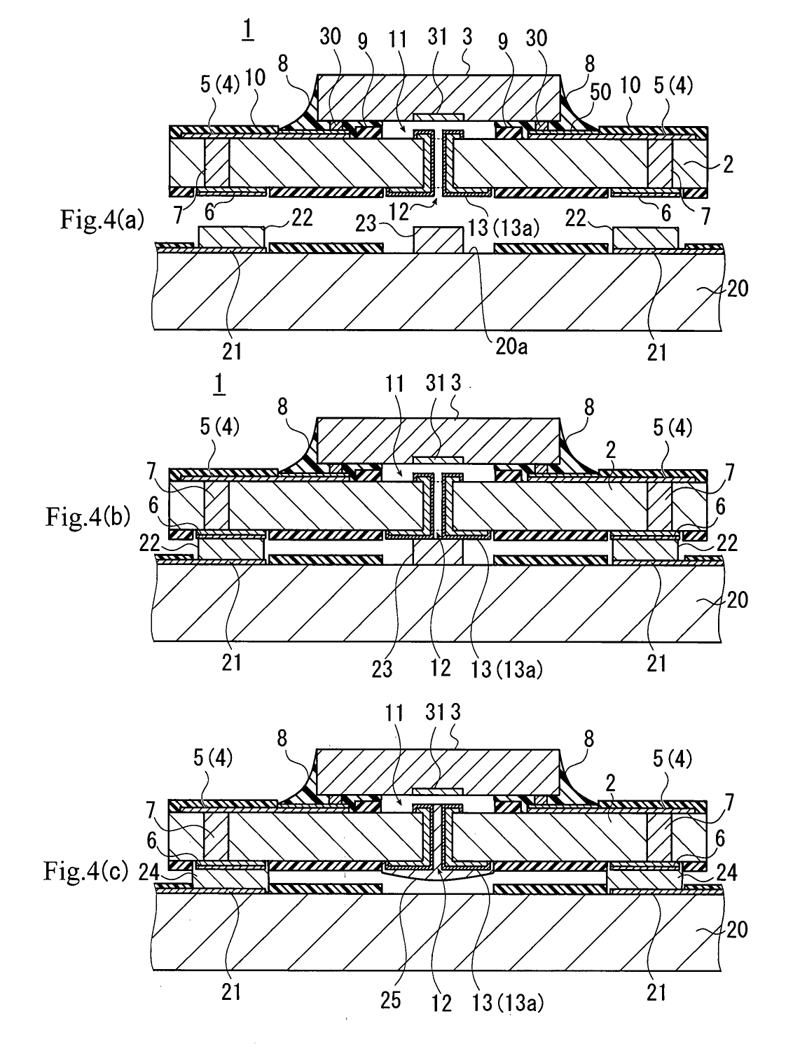

FIG. 4(a) to FIG. 4(c) are processing diagram showing an embodiment of the method for mounting the functional device-mounted module according to the present invention.

As shown in FIG. 4(a), in embodiments, solder pastes 22 and 23 are put, by printing, for example, on a connecting terminal 21 formed on a mounting substrate 20 and on a portion 20a of the mounting substrate 20 corresponding to the above introducing face 13a provided on the substrate 2 of the functional device-mounted module 1, respectively.

Although the kind of the solder paste 23 to be put on the portion 20a of the mounting substrate 20 corresponding to the solder-introducing portion 13a is not limited, a lead-free solder may be used in consideration of environmental responsiveness.

In this case, the solder paste 23 may be placed at a position corresponding to immediately under the hole 12 of the substrate 2 of the functional device-mounted module 1 from the standpoint of ensuring a seal.

Next, as shown in FIG. 4(b), the functional device-mounted module 1 is positioned and placed on the mounting substrate 20, so that the connecting terminal 6 and the above introducing face 13a are in contact with the solder pastes 22 and 23, respectively.

Then, the mounting substrate 20 and the functional device-mounted module 1 are placed, in a reflow furnace (not shown) and reflow soldering is performed at a given temperature.

By so doing, as shown in FIG. 4(c), the connecting terminal 21 of the mounting substrate 20 is fixed and electrically connected to the connecting terminal 6 of the functional device-mounted module 1 with the solder 24.

Water, etc. inside the receiving space 11 of the functional device-mounted module 1 are evacuated by reflow heating, whereas the solder 25 being contact with the introducing face 13a of the functional device-mounted module 1 flows into the hole 12 owing to its surface tension and closes the hole 12. As a result, the receiving space 11 of the functional device-mounted module is finally sealed in the state that water, etc. are evacuated.

As mentioned above, in embodiments, the sealing resin 8 can be prevented from interface debonding by the evaporation of the water inside the receiving space 11 on solder reflowing.

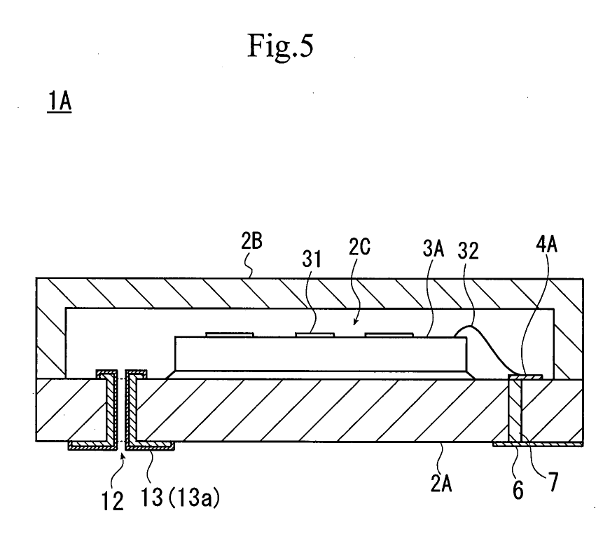

FIG. 5 is a schematic construction view showing another embodiment of the present invention. In the following, the same reference numerals are given to parts corresponding to those in the above embodiments, and their detailed explanation will be omitted.

As shown in FIG. 5, according to the functional device module 1A of an embodiment, a receiving space 2C is formed by placing a cavity-shaped lid 2B over the substrate 2A mounting the functional device 3A.

In this embodiment, connecting terminals 4A are electrically connected to the functional device 3A by bonding wires 32.

A connecting terminal 6 is formed on a back face of the substrate 2A, and this connecting terminal 6 is electrically connected to the connecting terminal 4A on the front face side via an electroconductive material 7 inside the through-hole.

In embodiments, a hole 12 communicating with the receiving space 2C is provided in an area other than an area where the functional device 3A is mounted on the substrate 2A, the hole 12 penetrates the back side of the substrate 2A.

Furthermore, a solder-introducing portion 13 (introducing face 13a) may be provided on the entire inner surface of the hole 12 and the surface-mounting portion on the back face side of the substrate 2 by continuously coating with a given metallic material that is compatible with solder, as in the above embodiment.

In embodiments having such a construction, the functional device-mounted module 1A is placed on a mounting substrate (not shown) on which solder pastes are put at predetermined positions and reflow soldering is performed.

In embodiments, the resin can be prevented from the interface debonding due to the evaporation of water inside the receiving space 2C on solder reflowing.

Particularly, embodiments be applied to various types of conventional device-mounted modules. Because construction, function and effects are the same as in the above-mentioned embodiment, detailed explanation thereof is omitted.

Note should be made that the present disclosure is not limited to the above embodiments, and various changes can be made.

According to the above embodiments, as an example, the solder-introducing portion may be provided by continuously coating the entire inner wall of the hole of the substrate and the surface-mounting portion on the back face side of the substrate. However, the construction of the solder-introducing portion is not limited to the above embodiments, so long as it can assuredly introduce the solder into the hole.

Furthermore, the provided position of the solder-introducing portion on the substrate and its number as well as the shape, the size, etc. of the hole can be appropriately changed depending upon the module used.

What is claimed is:

1. A functional device-mounted module in which a functional device having a given functional portion is mounted on a substrate formed with predetermined wiring patterns, the functional portion of the functional device arranged in a predetermined receiving space, and the functional device-mounted module comprising:
a hole formed on the substrate which communicates with the receiving space; and
a solder-introducing portion made of a metallic material that is compatible with solder in order to introduce the solder into the hole.

2. The functional device-mounted module according to claim 1, wherein the solder-introducing portion is formed by applying a coating onto an inner wall of the hole and along a surface mounting portion from the inner wall of the hole using the metallic material.

3. The functional device-mounted module according to claim 1, wherein the receiving space is formed between the functional portion of the functional device and the substrate by mounting the functional device on the substrate so as to face the functional portion to the substrate.

4. The functional device-mounted module according to claim 1, wherein the functional device is mounted on the substrate and arranged in the receiving space formed on the substrate having predetermined wiring patterns by covering the substrate with a lid.

5. A method for mounting a functional device-mounted module on a mounting substrate, wherein the device-mounted module comprises:
a functional device having a given functional portion mounted on a substrate formed with predetermined wiring patterns, the functional portion of the functional device is arranged in a predetermined receiving space;
a hole formed on the substrate which communicates with the receiving space; and
a solder-introducing portion made of a metallic material that is compatible with solder formed on the substrate in order to introduce the solder into the hole, wherein
the method for mounting comprises the steps of:
arranging the solder on the mounting substrate at a predetermined position;
placing the functional device-mounted module on a mounting substrate in a state that the hole is opposite to the solder; and
closing the hole by introducing the solder into the hole of the functional device-mounted module by melting the solder under heating.

6. The method for mounting the functional device-mounted module according to claim 5, wherein the step of introducing the solder into the hole is performed while electrically connecting a connecting terminal of the functional device-mounted module to a connecting terminal of the mounting substrate by reflow soldering.

7. The method for mounting the functional device-mounted module according to claim 5, wherein a functional device-mounted module is used in which the solder-introducing portion is formed by applying a coating on an inner wall of the hole and along a surface-mounting portion from the inner wall of the hole using the metallic material.

8. The method for mounting the functional device-mounted module according to claim 5, wherein a functional device-mounted module is used in which the receiving space is formed between the functional portion of the functional device and the substrate by mounting the functional device on the substrate so as to face the functional portion to the substrate.

9. The method for mounting the functional device-mounted module according to claim 5, wherein a functional device-mounted module is used in which the functional device is arranged in the receiving space formed on the substrate having predetermined wiring patterns by covering with a lid, and the functional device is mounted on the substrate.
